(19) United States
(12) Patent Application Publication
(10) Pub. No.: US 2026/0180596 A1
(43) Pub. Date: Jun. 25, 2026

(54) ADAPTIVE QUANTIZATION AND COMPRESSION FOR VARIABLE-LENGTH COLLECTIVE COMMUNICATION

(71) Applicants: ADVANCED MICRO DEVICES, INC., Santa Clara, CA (US); Xilinx Inc., San Jose, CA (US)

(72) Inventors: Venkata Pavan Kumar Miriyala, Chai Chee Road (SG); Lucian Petrica, Dublin (IE); Kenneth O'Brien, Dublin (IE)

(21) Appl. No.: 18/999,290

(22) Filed: Dec. 23, 2024

(51) Int. Cl. H03M 7/40; H03M 7/30

(52) U.S. Cl. CPC H03M 7/4031; H03M 7/3059; H03M 7/6011

(57) ABSTRACT

A processing system dynamically and selectively quantizes or compresses variable-length input data for a collective operation to fit within a predetermined limit, executes the collective operation on the compressed data, and converts the data back to variable length results by dequantizing or decompressing the results of the collective operation.

### BACKGROUND

Collective communication operations (also referred to as collective operations) are commonly used in neural networks and distributed systems. Collective operations are computations performed using multiple processors that alternate between computation and associated communication among the processors of data resulting from the computation. For example, in an all-to-all operation, each node of a group of nodes (also referred to as processes) has distinct data that is destined for each of the other nodes in the group. Through the all-to-all operation, each node sends an individual message including the distinct data to every other node of the group and each node receives its distinct data from every other node.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of a processing system configured to implement selective reduction of variable-length input data for collective operations in accordance with some embodiments.

FIG. 2 is a block diagram of a group of processes executing a collective operation in accordance with some embodiments.

FIG. 3 is a pair of diagrams illustrating sent and received variable-length input data for a collective operation in accordance with some embodiments.

FIG. 4 is a pair of diagrams illustrating selectively reduced variable-length input data for a collective operation in accordance with some embodiments.

FIG. 5 is a block diagram of a system architecture for selectively reducing variable-length input data for a collective operation in accordance with some embodiments.

FIG. 6 is a block diagram of a system architecture implementing a network device for selectively reducing variable-length input data for a collective operation in accordance with some embodiments

FIG. 7 is a flow diagram illustrating a method for selectively reducing variable-length input data for a collective operation in accordance with some embodiments.

### DETAILED DESCRIPTION

Collective operations typically use equal message size communications, in which each device, or process, sends and receives equal sized messages. However, neural networks in which a set of parameters are partitioned into disparate expert layers that send variable-length messages among devices, are gaining traction. Applications that send variable-length messages among devices include Mixture of Experts (MoEs) and deep learning recommendation models (DLRMs). MoEs perform variable-length communication collective operations (referred to herein as V-collectives or asymmetric collectives), which are collective operations performed by a group of processes connected by a network for which each process in the group exchanges variable amounts of data with all of the other processes in the group.

Typically, when executing a V-collective, each process first informs the other processes of the size of data the process will be transmitting to the other processes, in response to which each process allocates a transmit buffer sized to store the data the process will transmit to the other processes and a receive buffer sized to store the data the process will receive from the other processes such that no overflow of the receive buffer occurs upon receipt of the data. Once the transmit and receive buffers have been allocated, the processes exchange data using the buffers. However, exchanging the data sizes and allocating transmit and receive buffers of the required sizes results in poor network bandwidth utilization and increased latency arising from dynamic memory allocation.

To illustrate, the duration of a V-collective is

$$Tv ( Sx ) = Tf ( S x ) + T e ( S x ) + T a ( S x )$$

where Sx is a vector of input data sizes; Tv is the duration of the V-collective on data of input size Sx; Ta is the allocation time for buffers of sizes Sx at the receiver; Tf is the duration of a fixed-length collective (referred to herein as an F-collective) that transports the size vector Sx to receivers to allow them to allocate receive buffers; and Te is the duration of the transport of data of size Sx to the receivers. Although for large data sizes Te can be expected to dominate the overall duration Tv, for small and intermediate data sizes, or when network latencies are large, Tf and Ta can approach Te in runtime. In addition, executing V-collectives such as a variable-length all-to-all collective operation (alltoallv) using dynamic allocation of transmit and receive buffers is associated with drawbacks such as unexpected allocation failures, non-deterministic or unpredictable memory allocation delays, and memory management overheads. For example, if execution of a V-collective results in one device receiving more data than the other devices, transmitting data to the one device takes more time than transmitting data to the other devices, which must remain idle while waiting for transmission of the data to the one device. Further, unexpected allocation failures can occur if a received message size exceeds the available allocated buffer size for a process (e.g., if the process has to allocate additional memory separate from the buffer to store the message).

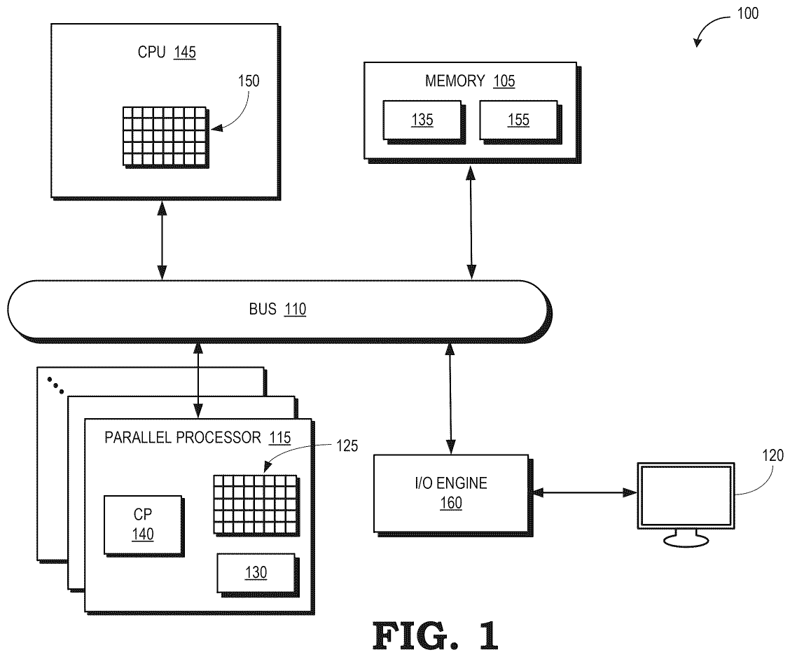

To facilitate processing of V-collectives while maintaining approximately the same performance profile as F-collectives, FIGS. 1-7 illustrate techniques to dynamically and selectively quantize or otherwise lossy-compress variable-length input data in the network to fit within a predetermined limit, execute an F-collective on the compressed data, and convert the data back to variable length results by dequantizing or decompressing the results of the F-collective. By selectively quantizing or compressing the variable-length input data to fit within a predetermined limit, the processing system eliminates the need for each process to inform the other processes of the size of data the process will be transmitting to the other processes and for each process to allocate transmit and receive buffers sized to store the variable-length data. In addition, communication delays and memory allocation failures are minimized or completely avoided, as each process receives a similar amount of data from all of the other processes.

In some implementations, the processing system allocates a buffer having a fixed size (e.g., corresponding to the predetermined limit) for each process and selectively reduces the size of the variable-length data to be sent or received from each process in response to the variable-length data exceeding the fixed size of the buffer. Thus, only those messages being sent or received by a process that collectively exceed the fixed size of the buffer are reduced, either by quantizing or compressing the variable-length data, while messages that collectively fit within the fixed size of the buffer are not quantized or compressed. Quantization and compression are lossy information processing techniques that can negatively impact model performance or accuracy for neural networks. Thus, in some implementations, the fixed size of the buffer is based on a tolerance to loss of precision of the sending or receiving process or of an application for which the collective operation is being executed.

Each portion of variable-length data to be sent or received from each process is associated with a priority in some implementations, with more important data having a higher priority than less important data. In such implementations, lower-priority portions of data are quantized or compressed first, or to a greater degree than the higher-priority portions of data, while higher-priority portions are quantized or compressed later, on an as-needed basis, or to a lesser degree than the lower-priority portions of data.

In some implementations, the processing system performs the quantization or compression at the process level. In such implementations, each process exchanges information regarding the amount of data they will be transferring to a particular receiving process. If the aggregate amount of data being transferred to the receiving process exceeds a predetermined limit (e.g., the fixed size of the buffer), the sending processes quantize or compress the data prior to transferring the data to the receiving process. Thus, performing quantization or compression at the process level requires communication among the processes.

In other implementations, the processing system performs the quantization or compression at the network level, e.g., at a network switch or a network device such as a smart network interface card (smart NIC) that connects the processes. In such implementations, each sending process indicates how much data it will be sending to a particular receiver. If the aggregate size of the messages from each sending process to the particular receiver exceeds the predetermined limit, the network switch or network device quantizes or compresses the data and transfers the reduced data to the receiving process. If the aggregate size of the messages intended for the particular receiver does not exceed the predetermined limit, the network switch or network device transfers the data in an unquantized and uncompressed state (i.e., transfers the data as is). Whether selective reduction of the data occurs at the process level or at the network level, the sending process or the network switch or device transmits to the receiving process metadata indicating the size of the variable-length input data and the quantization or compression algorithm that was applied to selectively reduce the amount of data being transmitted.

Once the receiving processes receive the selectively reduced data, the receiving processes execute the collective operation on the selectively reduced data to produce an output. Based on the metadata indicating the size of the variable-length input data and the quantization or compression algorithm that was applied to selectively reduce the amount of data being transmitted, the receiving process (or, in some implementations, the network) decompresses the output to match the size of the variable-length input data.

FIG. 1 is a block diagram of a processing system 100 configured to selectively quantize or compress variable-length input data for collective operations in accordance with some embodiments. The processing system 100 is generally configured to execute sets of instructions (e.g., programs) or commands (e.g., draw commands) to carry out tasks on behalf of an electronic device. Accordingly, in different embodiments the processing system 100 is incorporated into one of a variety of electronic devices, such as a desktop computer, laptop computer, server, smartphone, tablet, game console, and the like.

The processing system 100 includes or has access to a memory 105 or other storage component that is implemented using a non-transitory computer readable medium such as a dynamic random-access memory (DRAM). However, the memory 105 can also be implemented using other types of memory including static random-access memory (SRAM), nonvolatile RAM, and the like. The processing system 100 also includes a bus 110 to support communication between entities implemented in the processing system 100, such as the memory 105. Some embodiments of the processing system 100 include other buses, bridges, switches, routers, and the like, which are not shown in FIG. 1 in the interest of clarity.

The processing system 100 includes one or more parallel processors 115. A parallel processor is a processor that is able to execute a single instruction on multiple data or threads in a parallel manner. Examples of parallel processors include graphics processing units (GPUs), massively parallel processors, single instruction multiple data (SIMD) architecture processors, and single instruction multiple thread (SIMT) architecture processors for performing graphics, machine intelligence, or compute operations. The parallel processor 115 can render objects to produce pixel values that are provided to the display 120. In some implementations, parallel processors are separate devices that are included as part of a computer. In other implementations such as advance processor units, parallel processors are included in a single device along with a host processor such as a central processor unit (CPU). Thus, although embodiments described herein may utilize a graphics processing unit (GPU) for illustration purposes, various embodiments and implementations are applicable to other types of parallel processors.

In certain embodiments, the parallel processor 115 is also used for general-purpose computing. For instance, the parallel processor 115 can be used to implement machine learning algorithms such as one or more implementations of a neural network as described herein. In some cases, operations of multiple parallel processors 115 are coordinated to execute a machine learning algorithm, such as if a single parallel processor 115 does not possess enough processing power to run the machine learning algorithm on its own. The multiple processors 115 communicate over one or more network interfaces (not shown in FIG. 1 in the interest of clarity) such as a network switch or other network device (e.g., a smart NIC).

The parallel processor 115 implements multiple processing elements (also referred to as compute units) 125 that are configured to execute instructions concurrently or in parallel. The parallel processor 115 also includes an internal (or on-chip) memory 130 that includes a local data store (LDS), as well as caches, registers, or buffers utilized by the compute units 125. The internal memory 130 stores data structures that describe tasks executing on one or more of the compute units 125. In the illustrated embodiment, the parallel processor 115 communicates with the memory 105 over the bus 110. However, some embodiments of the parallel processor 115 communicate with the memory 105 over a direct connection or via other buses, bridges, switches, routers, and the like. The parallel processor 115 can execute instructions stored in the memory 105 and the parallel processor 115 can store information in the memory 105 such as the results of the executed instructions. For example, the memory 105 can store a copy 135 of instructions from a program code that is to be executed by the parallel processor 115 such as program code that represents a machine learning algorithm or neural network. The parallel processor 115 also includes a command processor 140 that receives task requests and dispatches tasks to one or more of the compute units 125. The command processor 140 is a set of hardware configured to receive the commands from the CPU 145 and to prepare the received commands for processing. For example, in some embodiments the command processor 140 buffers the received commands, organizes the received commands into one or more queues for processing, performs operations to decode or otherwise interpret the received commands, and the like.

The processing system 100 also includes a central processing unit (CPU) 145 that is connected to the bus 110 and communicates with the parallel processor 115 and the memory 105 via the bus 110. In the illustrated embodiment, the CPU 145 implements multiple processing elements (also referred to as processor cores) 150 that are configured to execute instructions concurrently or in parallel. The CPU 145 can execute instructions such as program code 155 stored in the memory 105 and the CPU 145 can store information in the memory 105 such as the results of the executed instructions. The CPU 145 is also able to initiate graphics processing by issuing commands or instructions (which are sometimes referred to herein as “draw calls”) to the parallel processor 115.

An input/output (I/O) engine 160 handles input or output operations associated with the display 120, as well as other elements of the processing system 100 such as keyboards, mice, printers, external disks, and the like. The I/O engine 160 is coupled to the bus 110 so that the I/O engine 160 communicates with the memory 105, the parallel processor 115, or the CPU 145.

In operation, the CPU 145 issues draw calls to the parallel processor 115 to initiate processing of a kernel that represents the program instructions that are executed by the parallel processor 115. Multiple instances of the kernel, referred to herein as threads or work items, are executed concurrently or in parallel using subsets of the compute units 125. In some embodiments, the threads execute according to single-instruction-multiple-data (SIMD) protocols so that each thread executes the same instruction on different data. The threads are collected into workgroups that are executed on different compute units 125. For example, the command processor 140 can receive the draw calls and schedule tasks for execution on the compute units 125.

One or more of the CPUs 145, the parallel processors 115, and the network interface (collectively referred to as processes) are configured as a group to execute variable-length lossless collective operations such as alltoallv, scatterv, gatherv, and allgatherv operations for which each process in the group exchanges variable amounts of data with all of the other processes in the group. To facilitate efficient processing of V-collectives, the processing system 100 converts the variable-length input data into nearly fixed-length data by selectively quantizing or compressing messages that exceed a predefined size limit for processes that send or receive more data than the predefined size limit.

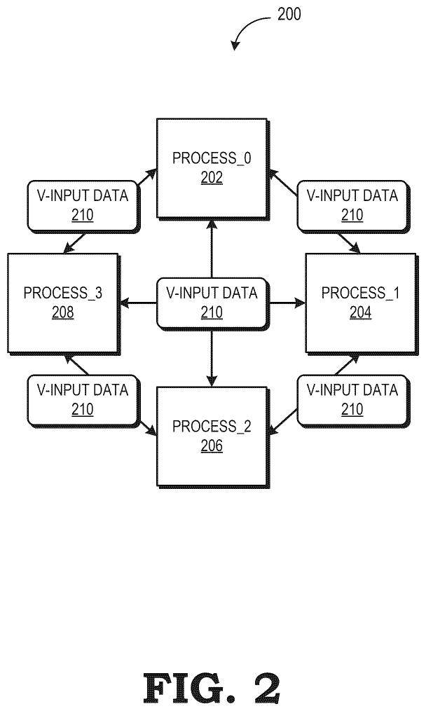

FIG. 2 is a block diagram of a group 200 of processes executing a collective operation in accordance with some embodiments. The group 200 includes process_0 202, process_1 204, process_2 206, and process_3 208 (collectively, processes 202-208). Each process 202-208 is a processing device such as a CPU, GPU, APU, DPU, or other accelerator unit, and together the group makes up a distributed computing system or computing device configured for alltoallv communication between the four devices. The illustrated example represents an all-to-all operation, and how the operation processes is based on underlying procedure, library calls, hardware configurations, etc. In this example, process_0 202 transmits variable-length input data 210 to each of process_0 202, process_1 204, process_2 206, and process_3 208; process_1 204 transmits variable-length input data 210 to each of the processes 202-208; process_2 206 transmits variable-length input data 210 to each of the processes 202-208; and process_3 transmits variable-length input data 210 to each of the processes 202-208. For an all-to-all operation, each of the processes 202-208 has respective variable-length input data 210, which is obtained or generated from a prior computation, and which is then shuffled between the devices using the all-to-all operation. The input data has a variable length, meaning that the amount of input data in a message transmitted by each process to each of the other processes (and itself) varies from one message to the next.

An implementation of alltoallv communication results in each of the processes (e.g., the four devices) in the distributed computing system forming the group 200 having output data corresponding to the input data that is received by each respective process. For example, the first process_0 202 has output data corresponding to the variable-length input data 210 received from itself (process_0 202), process_1 204, process_2 206, and process_3 208. Each of the processes 204-208 similarly has output data corresponding to the respective variable-length input data 210 received from all of the processes 202-208. Although this example is shown and described with reference to only four system nodes or devices, a distributed computing system can include any number of system nodes, devices, or clusters configured for all-to-all communication.

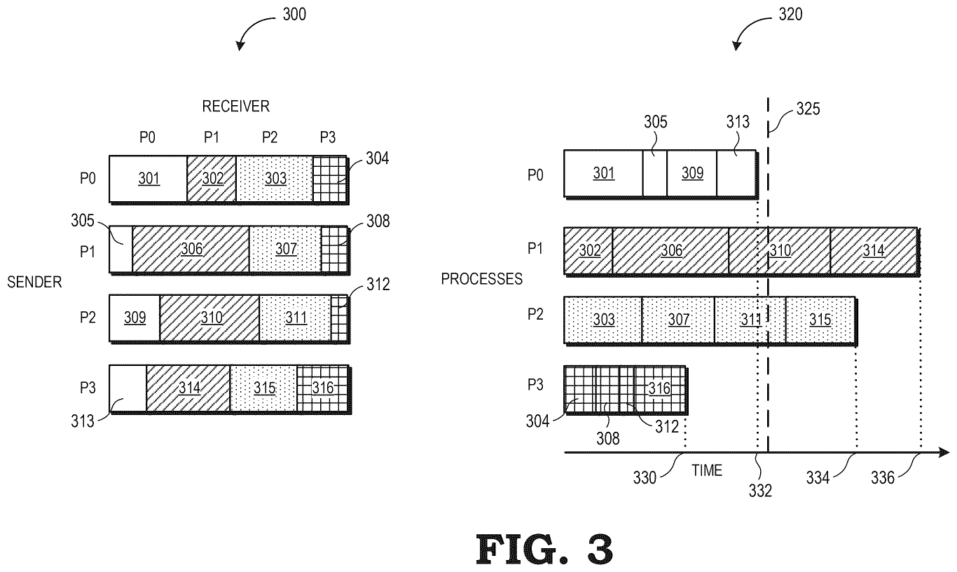

FIG. 3 is a pair of diagrams 300, 320 illustrating sent and received variable-length input data for a collective operation in accordance with some embodiments. Diagram 300 indicates blocks of variable-length input data being sent by and received at each of four processes, P0, P1, P2, and P3, which correspond respectively to process_0 202, process_1 204, process_2 206, and process_3 208 of FIG. 2. P0 transmits input data message 301 to itself (P0), input data message 302 to P1, input data message 303 to P2, and input data message 304 to P3. P1 transmits input data message 305 to P0, input data message 306 to itself (P1), input data message 307 to P2, and input data message 308 to P3. P2 transmits input data message 309 to P0, input data message 310 to P1, input data message 311 to itself (P2), and input data message 312 to P3. P3 transmits input data message 313 to P0, input data message 314 to P1, input data message 315 to P2, and input data message 316 to itself (P3).

Diagram 320 illustrates the differences in the aggregate quantity of data received by each of the four processes, P0, P1, P2, and P3. As measured by the amount of time it takes to transmit the respective aggregate quantities of data to each of the processes, P0, P1, P2, and P3, process P0 receives input data messages 301, 305, 309, and 313 in a first amount of time 332; process P1 receives input data messages 302, 306, 310, and 314 in a second amount of time 336; process P2 receives input data messages 303, 307, 311, and 315 in a third amount of time 334, and process P3 receives input data messages 304, 308, 312, 316 in a fourth amount of time 330.

The processing system 100 sets a predetermined limit 325 for the aggregate amount of data to be received by each of the processes P0, P1, P2, and P3. Aggregate amounts of data to be received by a process that exceed the predetermined limit 325 are quantized and/or compressed to fit within the predetermined limit 325. However, if the aggregate amount of data to be received by a process does not exceed the predetermined limit 325, the processing system 100 does not quantize or compress the variable-length input data. Thus, the processing system 100 selectively reduces the size of the variable-length input data based on an aggregate amount of data to be received by each of the processes. In some implementations, the processing system 100 selectively reduces the size of the variable-length input data based on an aggregate amount of data to be transmitted by each of the processes. Because both quantization and compression result in loss of precision of data, in some implementations, the predetermined limit 325 is based on at least one of a tolerance to loss of precision of the sending or receiving process or of an application for which the collective operation is being executed. For example, the predetermined limit 325 is learned as part of a training process for a neural network in some implementations in which the collective operation is executed in a machine learning application. In some implementations, the predetermined limit 325 is specified by a user.

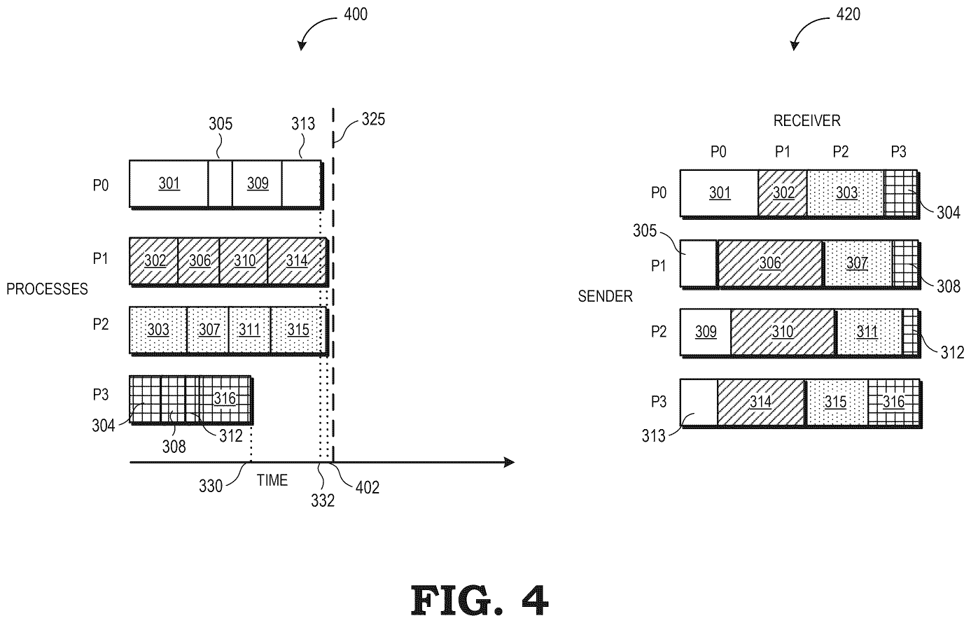

Because the aggregate amount of data to be received by processes P0 and P3 does not exceed the predetermined limit 325, the processing system 100 does not quantize or compress the variable-length input data 301, 305, 309, 313 to be received by process P0 or the variable-length input data 304, 308, 312, 316 to be received by process P3. However, because the aggregate amount of data to be received by processes P1 and P2 exceeds the predetermined limit 325, the processing system 100 quantizes or compresses the variable-length input data messages 302, 306, 310, 314 to be received by process P1 and the variable-length input data messages 303, 307, 311, 315 to be received by process P2, as shown in FIG. 4.

FIG. 4 is a pair of diagrams 400, 420 illustrating selectively reduced variable-length input data for a collective operation in accordance with some embodiments. Diagram 400 illustrates the differences in the aggregate quantity of selectively-reduced input data received by each of the four processes, P0, P1, P2, and P3. As measured by the amount of time it takes to transmit the respective aggregate selectively-reduced quantities of data to each of the processes, P0, P1, P2, and P3, process P0 receives input data messages 301, 305, 309, and 313 in a first amount of time 332 (i.e., an unchanged amount of time from that shown in diagram 320). Processes P1 and P2 receive reduced quantities of input data 302, 306, 310, and 314 and 303, 307, 311, and 315, respectively, in a second amount of time 402 that is less than the amounts of time 334, 336 that it would have taken to receive unquantized or uncompressed input data messages and that is also less than the predetermined amount of time 325. Process P3 receives input data messages 304, 308, 312, 316 in a third amount of time 336 (i.e., an unchanged amount of time from that shown in diagram 320).

The processing system 100 selectively reduces the variable-length input data destined for processes P1 and P2 by converting, e.g., floating-point 32 (fp32) variable-length input data to floating-point 16 (fp16) format or to integer format by applying a quantization algorithm in some implementations. In other implementations, the processing system 100 selectively reduces the variable-length input data that exceeds the predetermined limit 325 by compressing the variable-length input data (e.g., by discarding values that are zero or close to zero or performing delta compression) by applying a compression algorithm. In some implementations, the quantization and/or compression algorithm is selected at runtime based on the size of the variable-length input data, a target output size (e.g., predetermined limit 325), and a set of available algorithms. In addition to the data, each sending process P0, P1, P2, P3 also sends metadata (not shown) indicating how the selective quantization and/or compression was performed (i.e., the algorithm that was applied). In some implementations, the metadata is appended to the quantized/compressed data.

The quantized/compressed data is processed as it would be for an F-collective and is received at the destination process in compressed form, where it is stored at a buffer sized to store the predetermined limit of data in some implementations. The receiving process inspects the metadata and identifies the size of the original variable-length input data. The receiving process allocates a destination buffer sized to store the size of the original variable-length input data and dequantizes and/or decompresses the data based on the algorithm indicated by the metadata into the destination buffer.

The overall duration of a selectively-compressed collective operation (referred to herein as a VQ-collective) is

$$Tvq ( Sx , Sxc ) = Tf ( Sxc + Sm ) + Tc ( Sx , Sxc ) + Td ( Sxc , Sx )$$

Where Sx is a vector of input data sizes and Sxc is a scalar size of a preset destination buffer; Tvq is the duration of the VQ-collective on data of input size Sx with transmission size Sxc; Tc/Td are the compression and decompression/quantization and dequantization time from sizes Sx to size Sxc; and Tf is the duration of an F-collective that transports the size vector Sxc plus metadata of size Sm. Overall, the delay associated with a VQ-collective (Tvq) is lower than the delay associated with a variable collective (Tv).

Diagram 420 indicates blocks of selectively-reduced variable-length input data being sent by and received at each of the four processes, P0, P1, P2, and P3 following selective quantization and/or compression of the data based on the predetermined limit 325. In some implementations, the processing system 100 sets the predetermined limit 325 to minimize the variance in message sizes transmitted between devices (i.e., aggregate amounts of data sent from and received by each of the processes). If each of the processes is sending and receiving similar amounts of data, the transmission delays between devices will be similar, thereby improving performance.

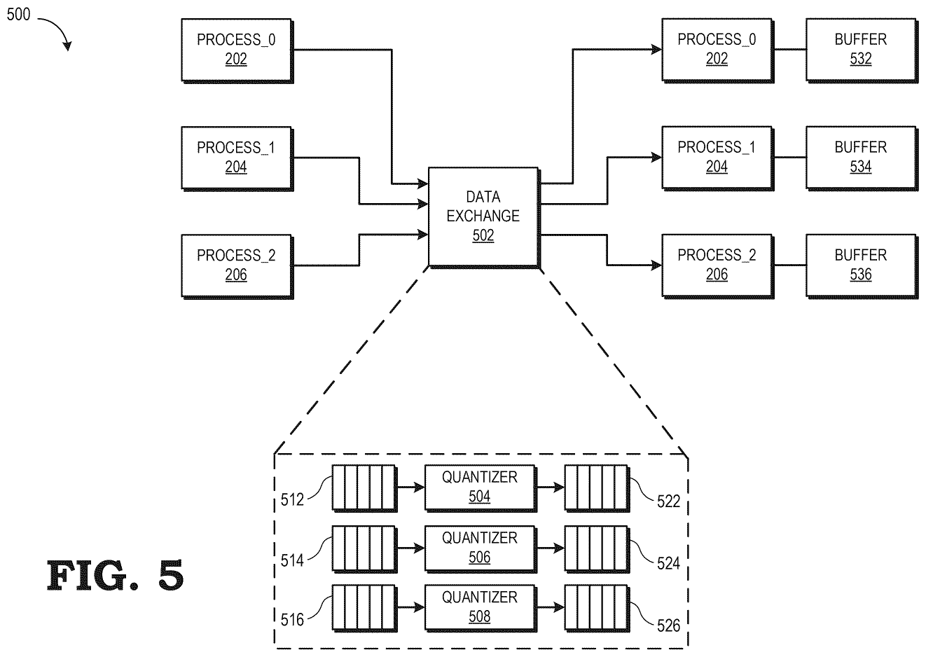

FIG. 5 is a block diagram of a system architecture 500 for selectively reducing variable-length input data such as variable-length input data 210 for a collective operation in accordance with some embodiments. In the illustrated example, process_0 202, process_1 204, and process_2 206 perform selective reduction of variable-length input data 210 at data exchange circuitry 502 before sending the data to the receiving processes. For example, process_0 202 sends variable-length input data (data_{xy}, data_{xz}) to receive buffer 512 of the data exchange circuitry 502. Process_1 204 sends variable-length input data (data_{yx}, data_{yz}) to receive buffer 514 of the data exchange circuitry 502, and process_2 206 sends variable-length input data (data_{zx}, data_{zy}) to receive buffer 516 of the data exchange circuitry 502. The receive buffers 512, 514, 516 are allocated based on the respective sizes of the variable-length input data. Because the receive buffers 512, 514, 516 have variable sizes to accommodate the variable-length input data, the VQ-collective implemented as illustrated in FIG. 5 is identical to a V-collective from the perspective of the sending processes.

The data exchange circuitry 502 compares the aggregate amounts of data sent to each of the processes 202, 204, 206 to the predetermined limit 325 and allocates send buffers 522, 524, 526 and receive buffers 532, 534, 536 for each of the processes 202, 204, 206 that are sized to store data having a size up to the predetermined limit 325. Quantizer 504 selectively reduces (i.e., quantizes and/or compresses) data stored at receive buffer 512 that exceeds the predetermined limit 325 and stores the selectively reduced data at the send buffer 522. Quantizer 506 selectively reduces data stored at receive buffer 514 that exceeds the predetermined limit 325 and stores the selectively reduced data at the send buffer 524. Quantizer 508 selectively reduces data stored at receive buffer 516 that exceeds the predetermined limit 325 and stores the selectively reduced data at the send buffer 526. The data exchange circuitry 502 then transmits the selectively reduced data to the receive buffers 532, 534, 536 of the respective processes 202, 204, 206 such that process_0 202 receives modified precision data (mod_precision_data_{yx}, mod_precision_data_{zx}), process_1 204 receives modified precision data (mod_precision_data_{xy}, mod_precision_data_{zy}), and process_2 206 receives modified precision data (mod_precision_data_{xz}, mod_precision_data_{yz}).

In some embodiments, the data exchange circuitry 502 is implemented within each of the processes 202, 204, 206. In such implementations, prior to selectively reducing the variable-length input data, each of the processes 202, 204, 206 exchanges information regarding the quantity of data each process is sending to each of the other processes. Each process 202, 204, 206 adds the amount of data it will be receiving from each of the processes to calculate an aggregate amount of data which it compares to the predetermined limit 325. If the aggregate amount of data exceeds the predetermined limit 325, the receiving process communicates to the other processes the amount by which the aggregate amount of data exceeds the predetermined limit 325. The sending processes 202, 204, 206 selectively reduce the variable-length input data accordingly and complete the data transfer to the receiving processes.

In some embodiments, the sending processes 202, 204, 206 implement the selective reduction of variable-length input data in software. The sending processes 202, 204, 206 then invoke an F-collective operation and reverse the selective reduction (i.e., quantization and/or compression) in software at the receiving process 202, 204, 206.

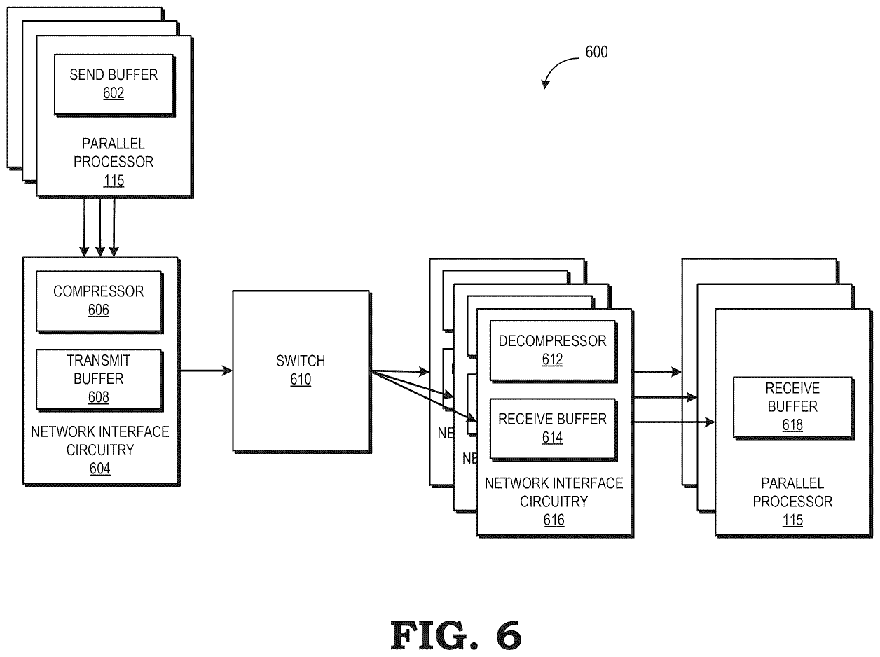

FIG. 6 is a block diagram of a system architecture 600 implementing a network device for selectively reducing variable-length input data such as variable-length input data 210 for a collective operation in accordance with some embodiments. In the illustrated example, each of the processes participating in the collective operation is a parallel processor such as parallel processor 115 that is connected to each of the other processes via network devices such as network interface circuitry 604, 616, and a switch 610.

The network interface circuitry 604, 616 is implemented as a network interface card (NIC) or smart NIC in some embodiments. The network interface circuitry 604, 616 is a hardware component that converts data packages to signals spread throughout the network. In some implementations, the network interface circuitry 604, 616 includes one or more accelerators or other processors configured to perform tasks such as networking, storage, security, data processing, load balancing, network management, and data compression and decompression. In the illustrated example, the network interface circuitry 604 includes a compressor 606 and a transmit buffer 608. The compressor is implemented as software and/or hardware configured to quantize and/or compress variable length input data 210 that exceeds the predetermined limit 325. The transmit buffer 608 is a buffer that is sized to store up to the predetermined limit 325 of data (i.e., Sxc).

Each parallel processor 115 includes a send buffer 602 that is sized to store variable-length input data that the parallel processor 115 sends to each of the parallel processors 115 participating in the collective operation. The parallel processors 115 transmit the variable-length input data to the network interface circuitry 604. In the illustrated example, a single instantiation of the network interface circuitry 604 receives the variable-length input data 210 from each of the parallel processors 115 and determines whether the aggregate variable-length input data destined for each of the parallel processors 115 exceeds the predetermined limit 325. If the aggregate variable-length input data destined for a given parallel processor 115 does not exceed the predetermined limit 325, the network interface circuitry 604 does not quantize or compress the variable-length input data and stores the variable-length input data at the transmit buffer 608. However, if the aggregate variable-length input data destined for a given parallel processor 115 exceeds the predetermined limit 325, the compressor 606 quantizes and/or compresses the variable-length input data 210 to fit within the predetermined limit 325 and stores the reduced data at the transmit buffer 608 with metadata indicating the original size of the variable-length input data 210 and the algorithm for quantization/compression that was applied to selectively reduce the data for transmission to the switch 610. Thus, the network interface circuitry 604 selectively reduces the variable-length input data to fit within the predetermined limit 325.

In other implementations, the system architecture 600 includes an instance of the network interface circuitry 604 for each parallel processor 115 participating in the collective operation. In such implementations, the network interface circuitries 604 exchange information regarding the respective sizes of the variable-length input data 210 destined for each of the parallel processors 115 and collectively determine whether the variable-length input data 210 destined for each parallel processor 115 fits within the predetermined limit 325. The multiple instances of the network interface circuitry 604 then selectively reduce the variable-length input data 210 and store the data at their respective transmit buffers 608 with metadata indicating the original size of the variable-length input data 210 and the algorithm for quantization/compression that was applied to selectively reduce the data for transmission to the switch 610.

The switch 610 is a network node such as a smart switch that performs the collective operation (i.e., the VQ-collective) on the selectively reduced data. In embodiments in which the selective reduction of the variable-length input data 210 results in a fixed-length output, the switch 610 performs an F-collective on the selectively reduced data. The switch 610 transmits the output of the collective operation with the metadata to a receive buffer 614 of the network interface circuitry 616. In the illustrated example, the network interface circuitry 616 is different from the network interface circuitry 604, but in other implementations, network interface circuitry 604, 616 are implemented in the same smart NIC, for example. The receive buffer 614 is sized to store data up to the predetermined limit 325 (i.e., Sxc), and in some embodiments, the receive buffer 614 is allocated in response to the predetermined limit 325 being set. In other embodiments, the sizing of the receive buffer 614 determines the predetermined limit 325. For example, in such embodiments, the processing system 100 allocates a receive buffer having a predetermined size, and the predetermined size of the receive buffer is the predetermined limit 325.

The network interface circuitry 616 includes a decompressor 612. The decompressor 612 is implemented as software and/or hardware configured to dequantize and/or decompress the output of the collective operation based on the metadata. For example, if the metadata indicates that the variable-length input data 210 had an original size Sx and was quantized/compressed using a particular algorithm, the decompressor 612 dequantizes/decompresses the output using the inverse of the particular algorithm to produce an output of size Sx for transmission to a receive buffer 618 at the receiving parallel processor 115. Although FIGS. 5 and 6 illustrate particular implementations in which the quantization/compression, the collective operation, and the dequantization/decompression are performed in the parallel processors 115, the network interface circuitry 604, 616, and the switch 610, in other embodiments the quantization/compression, the collective operation, and the dequantization/decompression are performed in any other combination of the CPUs 145, parallel processors 115, the network interface circuitry 604, 616, and the switch 610.

In some implementations, the network interface circuitry 616 does not dequantize/decompress the output but instead performs subsequent computations using the output with mixed precision. For example, if the variable-length input data 210 was in fp32 format and was selectively reduced (quantized) to fp16 format during transmission over the network, rather than decompressing the fp16 output back to fp32 format, the network interface circuitry 616 and/or the receiving parallel processor 115 executes mixed fp32-fp16 computations on the output data. In such implementations, the network interface circuitry 616 executes a user-defined processing strategy and launches the appropriate kernels on the parallel processor 115.

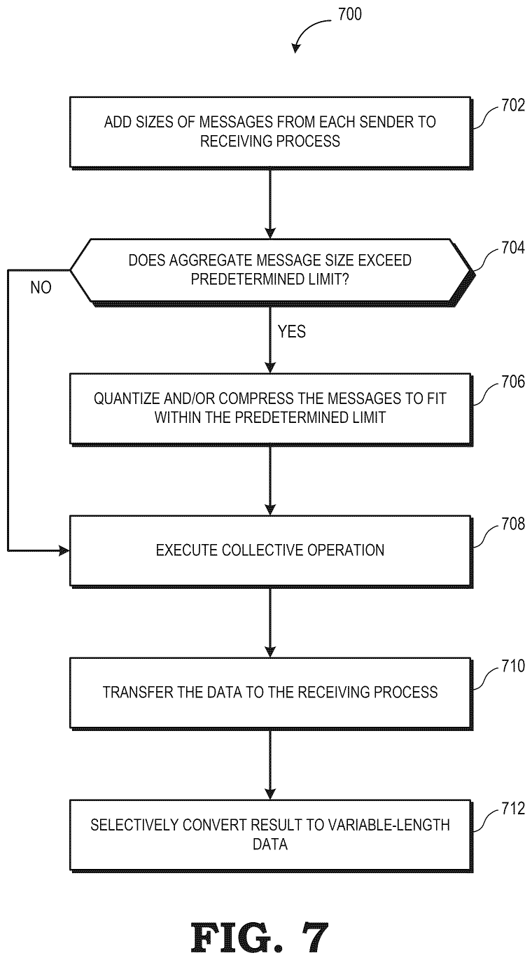

FIG. 7 is a flow diagram illustrating a method 700 for selectively reducing variable-length input data such as variable-length input data 210 for a collective operation in accordance with some embodiments. In some embodiments, the method 700 is implemented at a processing system such as processing system 100 having a system architecture such system architecture 500 or system architecture 600.

At block 702, the processing system adds the sizes of input data messages from each sending process to each receiving process. In some implementations, the sending processes communicate the sizes of the variable-length input data messages they are sending to each receiving process to the data exchange 502, to each other, or to the network interface circuitry 604.

At block 704, the processing system 100 compares the aggregate message size being sent by or received at each process to a predetermined limit such as predetermined limit 325. In some implementations, the predetermined limit 325 is set based on a size of an allocated receive buffer 532, 534, 536 or 614. If the aggregate message size exceeds the predetermined limit 325, the method flow continues to block 706. If the aggregate message size does not exceed the predetermined limit 325, the method flow continues to block 708.

At block 706, the processing system 100 quantizes and/or compresses the messages to fit within the predetermined limit 325. In some implementations, the quantization/compression algorithm is selected at runtime based on the size of the variable-length input data 210, the predetermined limit 325 (i.e., the target output size), and a set of available algorithms. In some implementations, elements of the arrays of variable-length input data 210 are associated with priorities such that higher-priority elements are compressed less than lower-priority elements. The priorities are learned as part of the training process for a neural network in some embodiments in which the collective operation is executed in a machine learning application. Depending on the implementation, the quantization/compression is performed at any one of the sending process, the data exchange 502, or the network interface circuitry 604.

At block 708, the processing system 100 executes the collective operation (the VQ-collective) on the selectively-reduced input data. In various implementations, the collective operation is executed at any of the processes, the network interface circuitry 604, or the switch 610.

At block 710, the output from the VQ-collective is transferred to a fixed size receive buffer such as receive buffer 532, 534, 536 or 614 at the receiving process or the network interface circuitry 616 with metadata indicating the original size of the variable-length input data 210 and the quantization/compression algorithm that was used to selectively reduce the input data. In some implementations, the receive buffer is allocated a predetermined size that sets the predetermined limit 325.

At block 712, the receiving process or the network interface circuitry 616 selectively converts the result to variable-length data having the same size as the original variable-length input data 210, based on the metadata. In some implementations, rather than dequantizing/decompressing the output data, the receiving process and/or the network interface circuitry 616 performs subsequent computations using the output data with mixed precision.

In some embodiments, the apparatus and techniques described above are implemented in a system including one or more integrated circuit (IC) devices (also referred to as integrated circuit packages or microchips), such as the processing system described above with reference to FIGS. 1-7. Electronic design automation (EDA) and computer aided design (CAD) software tools may be used in the design and fabrication of these IC devices. These design tools typically are represented as one or more software programs. The one or more software programs include code executable by a computer system to manipulate the computer system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool typically are stored in a computer readable storage medium accessible to the computing system. Likewise, the code representative of one or more phases of the design or fabrication of an IC device may be stored in and accessed from the same computer readable storage medium or a different computer readable storage medium.

A computer readable storage medium may include any non-transitory storage medium, or combination of non-transitory storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disk, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

One or more of the elements described above is circuitry designed and configured to perform the corresponding operations described above. Such circuitry, in at least some embodiments, is any one of, or a combination of, a hardcoded circuit (e.g., a corresponding portion of an application specific integrated circuit (ASIC) or a set of logic gates, storage elements, and other components selected and arranged to execute the ascribed operations), a programmable circuit (e.g., a corresponding portion of a field programmable gate array (FPGA) or programmable logic device (PLD)), or one or more processors executing software instructions that cause the one or more processors to implement the ascribed actions. In some embodiments, the circuitry for a particular element is selected, arranged, and configured by one or more computer-implemented design tools. For example, in some embodiments the sequence of operations for a particular element is defined in a specified computer language, such as a register transfer language, and a computer-implemented design tool selects, configures, and arranges the circuitry based on the defined sequence of operations.

Within this disclosure, in some cases, different entities (which are variously referred to as “components,” “units,” “devices,” “circuitry,” etc.) are described or claimed as “configured” to perform one or more tasks or operations. This formulation-[entity] configured to [perform one or more tasks]—is used herein to refer to structure (i.e., something physical, such as electronic circuitry). More specifically, this formulation is used to indicate that this physical structure is arranged to perform the one or more tasks during operation. A structure can be said to be “configured to” perform some task even if the structure is not currently being operated. A “memory device configured to store data” is intended to cover, for example, an integrated circuit that has circuitry that stores data during operation, even if the integrated circuit in question is not currently being used (e.g., a power supply is not connected to it). Thus, an entity described or recited as “configured to” perform some task refers to something physical, such as a device, circuitry, memory storing program instructions executable to implement the task, etc. This phrase is not used herein to refer to something intangible. Further, the term “configured to” is not intended to mean “configurable to.” An unprogrammed field programmable gate array, for example, would not be considered to be “configured to” perform some specific function, although it could be “configurable to” perform that function after programming. Additionally, reciting in the appended claims that a structure is “configured to” perform one or more tasks is expressly intended not to be interpreted as having means-plus-function elements.

In some embodiments, certain aspects of the techniques described above may be implemented by one or more processors of a processing system executing software. The software includes one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. A method comprising:
allocating a buffer having a fixed size for each process of a plurality of processes;
selectively reducing a size of variable-length input data scheduled to be transferred between a first process of the plurality of processes and the other processes of the plurality of processes for a collective operation based on the variable-length input data exceeding the fixed size of the buffer; and
transmitting the data to the buffer.

2. The method of claim 1, wherein the fixed size of the buffer is based on a tolerance to loss of precision of at least one of the first process and an application comprising the collective operation.

3. The method of claim 1, wherein reducing the data comprises at least one of quantizing the variable-length input data and compressing the variable-length input data.

4. The method of claim 1, further comprising:
transmitting metadata comprising an indication of a quantization or compression algorithm applied for the selective reducing to the buffer.

5. The method of claim 1, further comprising:
executing the collective operation on the selectively reduced input data at each process of the plurality of processes to produce an output.

6. The method of claim 5, further comprising:
selectively converting the output to a size of the variable-length input data.

7. The method of claim 1, wherein the variable-length input data comprises aggregate input data from each process of the plurality of processes to be received by the first process.

8. A method, comprising:
selectively reducing a precision of an aggregate of variable-length input data scheduled to be received by each process of a plurality of processes from other processes of the plurality of processes for a collective operation based on the aggregate of variable-length input data exceeding a predefined size limit; and
transmitting the selectively reduced-precision input data to each process.

9. The method of claim 8, wherein the predefined size limit is based on a tolerance to loss of precision of at least one of each process and an application comprising the collective operation.

10. The method of claim 8, wherein reducing the precision of the aggregate of variable-length input data comprises at least one of quantizing the aggregate of variable-length input data and compressing the aggregate of variable-length input data.

11. The method of claim 8, further comprising:
transmitting metadata comprising an indication of a quantization or compression algorithm applied for the selective reducing to each process.

12. The method of claim 8, further comprising:
executing the collective operation at each process of the plurality of processes to produce a fixed-length output.

13. The method of claim 12, further comprising:
selectively converting the fixed-length output to a size of the variable-length input data.

14. The method of claim 8, wherein an amount of the selectively reducing is based on a priority of the variable-length input data.

15. The method of claim 14, wherein the priority of the variable-length input data is learned in a training process for a neural network.

16. A processing system, comprising:
a plurality of processes, each process of the plurality of processes configured to send variable-length input data to each of the other processes of the plurality of processes; and
a network interface linking the processes configured to selectively reduce a precision of an aggregate of variable-length input data scheduled to be received by each process of the plurality of processes from the other processes of the plurality of processes for a collective operation based on the aggregate of variable-length input data exceeding a predefined size limit.

17. The processing system of claim 16, wherein the predefined size limit is based on a tolerance to loss of precision of at least one of each process and an application comprising the collective operation.

18. The processing system of claim 16, wherein the network interface is to selectively reduce the precision of the aggregate of variable-length input data by least one of quantizing the aggregate of variable-length input data and compressing the aggregate of variable-length input data.

19. The processing system of claim 16, further comprising:
a switch configured to execute the collective operation to produce a fixed-length output.

20. The processing system of claim 19, further comprising:
a buffer for each process of the plurality of processes configured to store the predefined size limit of data and to receive the fixed-length output.
